(19) United States
(12) Patent Application Publication
(10) Pub. No.: US 2009/0296322 A1
(43) Pub. Date: Dec. 3, 2009

(54) CASE UNIT FOR STORAGE DEVICE

(75) Inventors: Shin-Hsun Yang, Taipei City (TW); Te-Sheng Liu, Taichung City (TW); Chih-Pin Chen, Taipei City (TW); Kuo-Kuang Liu, Nantou County (TW); Chien-Ta Lin, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: UNIVERSAL SCIENTIFIC INDUSTRIAL CO., LTD, TSAO TUEN (TW)

(21) Appl. No.: 12/131,628

(22) Filed: Jun. 2, 2008

(51) Int. Cl. H05K 7/14

(52) U.S. Cl. 361/679.01

(57) ABSTRACT

A case unit for a storage device includes a main case having an accommodation chamber, a subsidiary case detachably and drawably mounted in the accommodation chamber of the main case, and a circuit board mounted with the subsidiary case. As long as the subsidiary case is taken out of the accommodation chamber of the main case, the circuit board can be repaired, thereby enhancing convenience of assembly and repair works.

### BACKGROUND OF THE INVENTION

1. Field of the Invention

The present invention relates generally to a storage device, and more specifically to a case unit that is used in a storage device.

2. Description of the Related Art

A conventional storage device mainly includes a case with a plurality of sockets and a plurality of hard disks respectively received in the sockets and electrically connected to a circuit board mounted in the case.

When the circuit board is malfunction and then needs to be repaired, a maintenance worker has to dismount a top cover of the case from two opposite side plates of the case in order to take the circuit board out of the case. However, the top cover is generally screwed to the two opposite side plates of the case such that the maintenance worker has to use a screwdriver to remove screws one by one for enabling the dismounting work of the top cover from the two opposite side plates of the case. Thus, it can be seen that the conventional case of the storage device has the drawback of inconvenient assembly, resulting in inconvenient repair of the circuit board.

### SUMMARY OF THE INVENTION

The present invention has been accomplished in view of the above-noted circumstances. It is one objective of the present invention to provide a case unit, which is convenient in assembly and repair works.

To achieve this objective of the present invention, the case unit comprises a main case having an accommodation chamber, a subsidiary case detachably mounted in the accommodation chamber of the main case, and a circuit board mounted with the subsidiary case.

When the circuit board needs to be repaired, the subsidiary case can be easily taken out of the accommodation chamber of the main case and then the circuit board can be easily detached from the subsidiary case for repair work.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded view of the case unit according to a preferred embodiment of the present invention;

FIG. 2 is similar to FIG. 1, but showing that the circuit board is mounted to the subsidiary case, and

FIG. 3 is a perspective view of the case unit according to the preferred embodiment of the present invention, in which the top cover of the main case is removed for illustrative purpose.

### DETAILED DESCRIPTION OF THE INVENTION

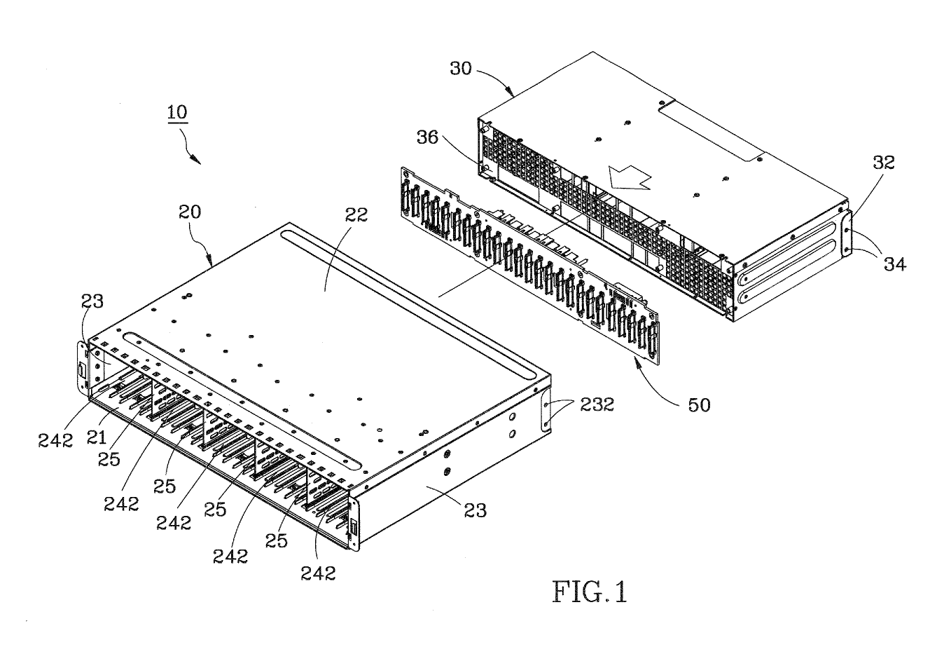

As shown in FIG. 1, a case unit 10 for a storage device, such as a server, in accordance with a preferred embodiment of the present invention comprises a main case 20, a subsidiary case 30, two fasteners 40, and a circuit board 50.

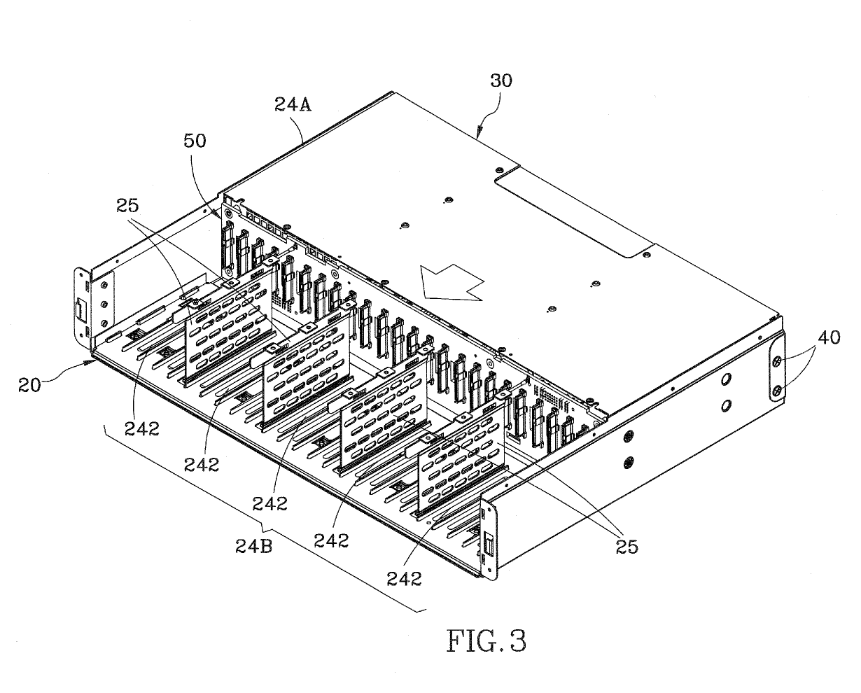

The main case 20 includes a bottom plate 21, a top cover 22, and two lateral plates 23. Each lateral plate 23 has two first fixing hole 232, and top and bottom sides thereof respectively fixed to one of left and right sides of the bottom plate 21 and the top cover 22 such that two accommodation chambers 24A and 24B in communication with each other are defined by the bottom plate 21, the top cover 22, and the lateral plates 23, as shown in FIG. 3. Further, the main case 20 includes a plurality of partitions 25 mounted in the accommodation chamber 24B to divide the accommodation chamber 24B into a plurality of sockets 242 for accommodation of hard disks (not shown).

The subsidiary case 30, which is used for installation of a power supply (not shown) and a motherboard (not shown), has a shape comparable to that of the accommodation chamber 24A of the main case 20 and a dimension smaller than that of the accommodation chamber 24A of the main case 20 such that the subsidiary case 30 can be drawably received in the accommodation chamber 24A of the main case 20. In addition, the subsidiary case 30 is provided at each one of two opposite lateral sides thereof with a clipping portion 32 which can be clipped to one of the lateral plates 23 of the main case 20 when the subsidiary case 30 is received in the main case 20. The subsidiary case 30 includes two second fixing holes 34 formed on each one of the clipping portions 32 and aligned with the first fixing holes 34 of the main case 20 when the subsidiary case 30 is received in the main case 20. Further, the subsidiary case 30 is mounted with a heat sink 36 at a front side thereof.

As shown in FIG. 3, the fastener 40, which is embodied as a screw in this exemplary embodiment, is screwed to the first fixing hole 232 of the main case 20 and the second fixing hole 34 of the subsidiary case 30 for fixing the main case 20 and the subsidiary case 30 together.

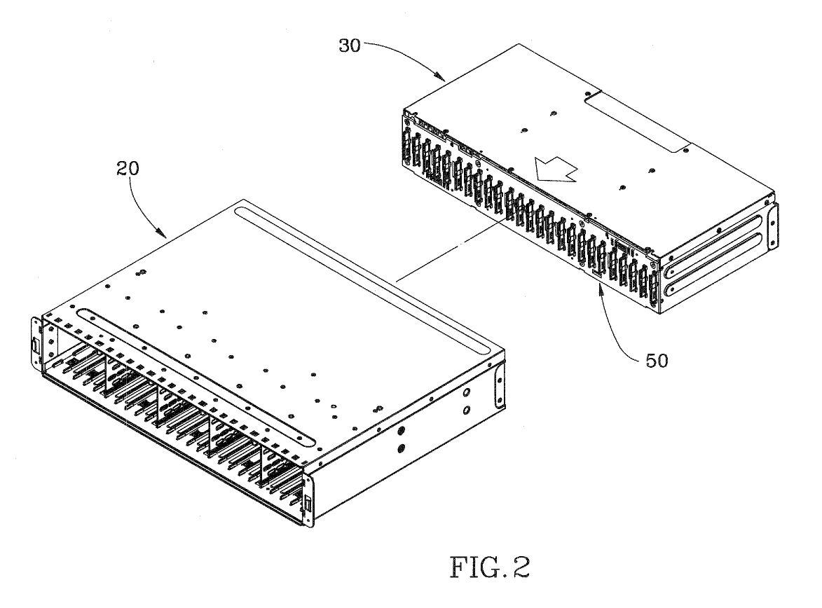

As shown in FIG. 2, the circuit board 50 is mounted to the heat sink 36 of the subsidiary case 20 so as to be located in the accommodation chamber 24A of the main case 20. As a result, the power supply and the motherboard inside the subsidiary case 30 can be electrically connected to the hard disks inside the main case 20.

By means of the aforesaid design, when the circuit board 50 is malfunction and then needs to be repaired, a maintenance worker can use a screwdriver to remove the fasteners 40, then draw the subsidiary case 30 out of the accommodation chamber 24A of the main case 20, and then dismount the circuit board 50 from the heat sink 36 of the subsidiary case 30. As a result, the circuit board 50 can be repaired or replaced. After the repair or the replacement of the circuit board 50 is completed, the maintenance worker can fasten the circuit board 50 to the heat sink of the subsidiary case 30 first, then place the subsidiary case 30 in the accommodation 24A of the main case 20 to enable the clipping portions 32 or the subsidiary case 30 to be clipped to the lateral plates 23 of the main case 20, and then screw the fasteners 40 by using the screwdriver so as to complete the assembly of the case unit 10.

As indicated above, the case unit of the present invention can be easily assembled and disassembled, thereby enhancing the convenience of assembly and repair works.

Certainly, the inner structure of the main case and the inner structure of the subsidiary case can be exchanged but not limited to the above-mentioned embodiment. In other words, the partitions can be designed to be mounted in the subsidiary case to divide the inside of the subsidiary case into a plurality of sockets for installation of the hard disks, and the power supply and the motherboard can be installed in the inside of the main case. Under this circumstance, when the subsidiary case is received in the accommodation chamber of the main case, the hard disks inside the subsidiary case still can be electrically connected to the power supply and the motherboard inside the main case for achieving the objective of the present invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A case unit for a storage device, the case unit comprising:
a main case having an accommodation chamber;
a subsidiary case detachably mounted in the accommodation chamber of the main case; and
a circuit board mounted with the subsidiary case.

2. The case unit as claimed in claim 1, wherein one side of the subsidiary case has a heat sink connected to the circuit board.

3. The case unit as claimed in claim 1, wherein the subsidiary case is provided at each of two opposite sides thereof with a clipping portion clipped to one of two opposite sides of the main case.

4. The case unit as claimed in claim 3, further comprising two fasteners, each of which is fastened to a first fixing hole of one of the two opposite sides of the main case and a second fixing hole of one of the clipping, portions of the subsidiary case.
